(19) United States
(12) Patent Application Publication
(10) Pub. No.: US 2025/0221278 A1
(43) Pub. Date: Jul. 3, 2025

(54) DISPLAY DEVICE

(71) Applicant: Samsung Display Co., Ltd., Yongin-si (KR)

(72) Inventors: YOUNGSANG HA, Yongin-si (KR); RANGKYUN MOK, Yongin-si (KR); SU-YEON SIM, Yongin-si (KR); TAEHO LEE, Yongin-si (KR)

(73) Assignee: Samsung Display Co., Ltd., Yongin-si (KR)

(21) Appl. No.: 18/925,385

(22) Filed: Oct. 24, 2024

(30) Foreign Application Priority Data
Dec. 28, 2023 (KR) 10-2023-0195184

(51) Int. Cl. H10K 59/80; G02B 3/00; G02B 3/08; H05K 5/02; H10K 102/00

(52) U.S. Cl. CPC H10K 59/879; G02B 3/005; G02B 3/08; H05K 5/0217; H10K 59/873; H10K 59/8792; H10K 2102/311

(57) ABSTRACT

A display device includes an electronic panel, a plurality of lenses disposed on the electronic panel, arranged in a first direction, and extending in a second direction intersecting the first direction, and a plurality of joint parts respectively disposed on the plurality of lenses and rotatably coupled to each other.

### CROSS-REFERENCE TO RELATED APPLICATIONS

This U.S. non-provisional patent application claims priority to and benefits of Korean Patent Application No. 10-2023-0195184 under 35 U.S.C. § 119, filed on Dec. 28, 2023, in the Korean Intellectual Property Office (KIPO), the entire contents of which are incorporated herein by reference.

### BACKGROUND

The disclosure herein relates to a display device.

An electronic apparatus, such as a smartphone, a digital camera, a laptop, a navigation, and a smart television, which provides an image to a user, includes a display device for displaying the image. The display device generates an image and provides the image to a user through a display screen.

Recently, with development of display device technology, display devices in various forms have been developed. For example, various flexible display devices capable of being deformed to have a curved shape, folded, or rolled have been developed. The flexible display devices may be readily carried and improve user convenience.

Among the flexible display devices, a rollable display device includes a display module, a roller on which the display module is wound, and a housing for accommodating the display module and the roller. The roller may rotate, and the display module may be pulled out from or pulled into the housing.

### SUMMARY

The disclosure provides a rollable display device capable of providing a dual image.

In an embodiment of the inventive concept, a display device includes an electronic panel, a plurality of lenses disposed on the electronic panel, arranged in a first direction, and extending in a second direction intersecting the first direction, and a plurality of joint parts respectively disposed on the plurality of lenses and rotatably coupled to each other.

A side of an h-th joint part and a side of an (h+1)-th joint part may be adjacent to each other and coupled to each other to rotate with respect to a rotating axis parallel to the second direction so as to be defined as a rotary coupling portion, the rotary coupling portion may be disposed between an h-th lens and an (h+1)-th lens, and h may be a natural number.

A lower portion of the rotary coupling portion may have a downwardly convex curved surface.

The display device may further include a light blocking layer disposed under the lower portion of the rotary coupling portion.

The h-th lens and the (h+1)-th lens may be respectively attached to a flat portion of the h-th joint part adjacent to the side of the h-th joint part and a flat portion of the (h+1)-th joint part adjacent to the side of the (h+1)-th joint part.

The display device may further include a plurality of resin layers, between the plurality of lenses and the electronic panel, respectively disposed under the plurality of lenses.

The plurality of lenses may have greater elastic modulus than the plurality of resin layers.

The plurality of lenses may be respectively disposed in a plurality of grooves defined in the plurality of resin layers to face the plurality of lenses.

The display device may further include a first adhesive layer disposed between the electronic panel and the plurality of resin layers.

The display device may further include a window disposed on the plurality of joint parts; and a second adhesive layer disposed between the window and the plurality of joint parts.

A refractive index of the plurality of lenses may be greater than a refractive index of the plurality of resin layers, and a refractive index of the window may be smaller than the refractive index of the plurality of lenses.

The plurality of lenses may include a transparent metal.

The plurality of lenses may include a metal material having a Knoop hardness in a range of about 1500 kg/mm² to about 2500 kg/mm².

When viewed in the second direction, the plurality of lenses may each have a shape of an inverted triangle.

When viewed in the second direction, the plurality of lenses may each have a downwardly convex shape.

The electronic panel may include a plurality of first pixels and a plurality of second pixels alternately disposed in the first direction, and a pair of a first pixel and a second pixel which are adjacent to each other may be disposed so that the first pixel and the second pixel are disposed on left and right sides of a corresponding lens, among the plurality of lenses, with respect to a central portion of the corresponding lens, when view on a plan.

The electronic panel may be wound or unwound according to rotation of the plurality of joint parts, and in case that the electronic panel is unwound, the plurality of lenses may support the electronic panel in a flat state.

In an embodiment of the inventive concept, a display device includes an electronic panel, a plurality of lenses disposed on the electronic panel, arranged in a first direction, and extending in a second direction intersecting the first direction, a plurality of light blocking layers disposed between the plurality of lenses, a first resin layer disposed between the plurality of lenses and the electronic panel and between the plurality of light blocking layers and the electronic panel, and a second resin layer disposed on the plurality of lenses and the plurality of light blocking layers. The first resin layer and the second resin layer include a same material.

The electronic panel may include a plurality of first pixels and a plurality of second pixels alternately disposed in the first direction, and a pair of a first pixel and a second pixel which are adjacent to each other may be disposed so that the first pixel and the second pixel are disposed on left and right sides of a corresponding lens, among the plurality of lenses, with respect to a central portion of the corresponding lens, when view on a plan.

An upper surface of each of the plurality of lenses and an upper surface of each of the plurality of light blocking layers may be disposed on a same plane.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1 and 2 are schematic diagrams illustrating the inside of a vehicle in which a display device according to an embodiment of the inventive concept is disposed;

FIG. 3 is a schematic diagram illustrating that an image generated from the display device in FIGS. 1 and 2 is provided to users;

FIG. 4 is a schematic perspective view of a display device according to an embodiment of the inventive concept;

FIG. 5 is a schematic diagram illustrating that the display device in FIG. 4 is in an expansion mode;

FIG. 6 is a schematic diagram illustrating a rear of a display device in the expansion mode in FIG. 5;

FIG. 7 is a schematic diagram illustrating a display module accommodated in a housing in FIGS. 4 and 5 in a flat state;

FIG. 8 is a schematic diagram illustrating that a display module in FIG. 7 is wound;

FIG. 9 is a schematic diagram of a cross section of the display module in FIG. 7;

FIG. 10 is a schematic cross-sectional view of an electronic panel showing a configuration of an electronic panel in FIG. 9;

FIG. 11 is a schematic cross-sectional view of a display panel showing a configuration of a display panel in FIG. 10;

FIG. 12 is a schematic plan view of the display panel in FIG. 11;

FIG. 13 is a schematic cross-sectional view taken along line I-I′ in FIG. 7;

FIG. 14 is a schematic perspective view of any one lens and resin layer in FIG. 13;

FIG. 15 is a schematic exploded perspective view of an h-th joint unit and an (h+1)-th joint unit, which are adjacent to each other, among joint units in FIG. 13;

FIG. 16 is a schematic diagram illustrating that a display module in FIG. 13 is bent;

FIG. 17 is a schematic diagram showing a configuration of an optical layer according to another embodiment of the inventive concept;

FIG. 18 is a schematic diagram illustrating that a display module in FIG. 17 is bent;

FIG. 19A is a schematic diagram illustrating refraction of first light by lenses in FIG. 13 as a simulation result;

FIG. 19B is a schematic diagram illustrating refraction of second light by the lenses in FIG. 13 as a simulation result;

FIG. 20 is a diagram illustrating luminance of the first light and the second light in FIGS. 19A and 19B as a simulation result;

FIG. 21A is a schematic diagram illustrating refraction of first light by lenses in FIG. 17 as a simulation result;

FIG. 21B is a schematic diagram illustrating refraction of second light by the lenses in FIG. 17 as a simulation result;

FIG. 22 is a schematic diagram illustrating luminance of the first light and the second light in FIGS. 21A and 21B as a simulation result;

FIG. 23 is a schematic diagram showing a configuration of an optical layer according to another embodiment of the inventive concept;

FIG. 24 is a schematic diagram illustrating that a display module in FIG. 23 is bent;

FIG. 25 is a schematic diagram showing a configuration of an optical layer according to another embodiment of the inventive concept;

FIGS. 26A to 26D are schematic diagrams for describing a method of manufacturing the display module in FIG. 13;

FIGS. 27A to 27C are schematic diagrams for describing a method of aligning an optical layer and an electronic panel; and

FIGS. 28A to 28D are schematic diagrams for describing a method of manufacturing the display module in FIG. 23.

### DETAILED DESCRIPTION OF THE EMBODIMENTS

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween.

Like reference numerals or symbols refer to like elements throughout. Also, in the drawings, the thicknesses, the ratios, and the dimensions of elements may be exaggerated for effective description of technical contents.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Although the terms first, second, etc. may be used herein to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well unless the context clearly indicates otherwise.

Also, terms such as “below”, “lower”, “above”, “upper” are used to describe the relationships of the elements illustrated in the drawings. These terms have relative concepts and are described on the basis of the directions indicated in the drawings.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the inventive concept belongs. In addition, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the terms such as “include,” “comprise,” or “have”, when used herein, are intended to specify the presence of stated features, integers, steps, operations, elements, components, or combinations thereof, but do not preclude the presence or addition of one or more other features, integers, steps, operations, elements, components, or combinations thereof.

Hereinafter, embodiments of the inventive concept will be described with reference to the accompanying drawings.

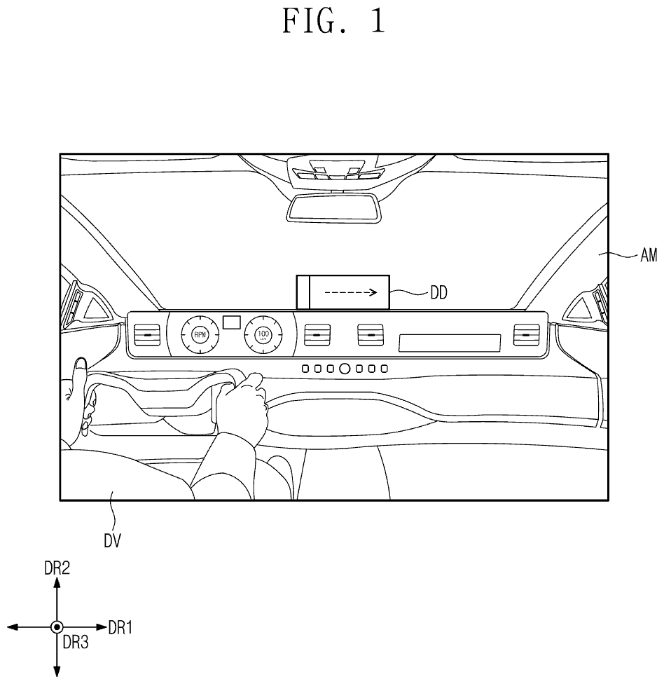

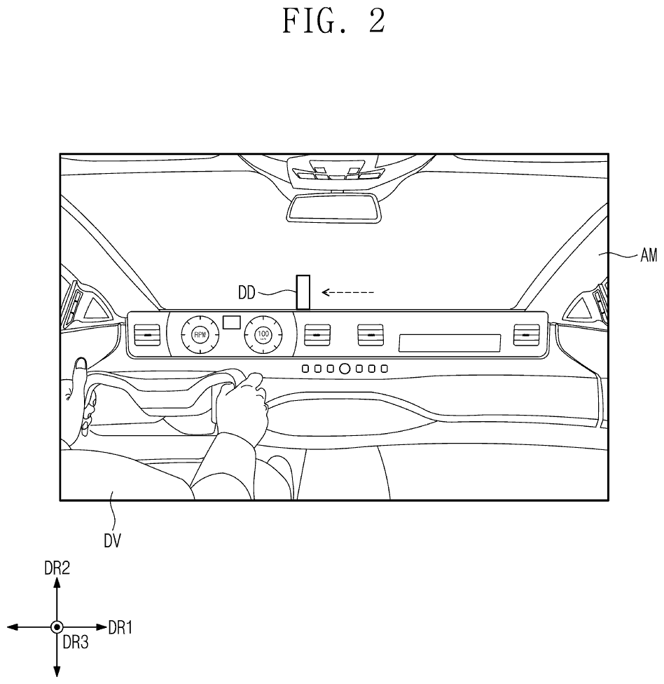

FIGS. 1 and 2 are schematic diagrams illustrating the inside of a vehicle in which a display device according to an embodiment of the inventive concept is disposed.

Referring to FIGS. 1 and 2, a display device DD may be disposed inside a vehicle AM. The display device DD may be disposed inside the vehicle AM to provide various pieces of information to a driver DV (or a user). The display device DD may provide an image such as a weather image, a speed image, a map image, or a movie image to the driver DV. The display device DD may be a touch display which operates in response to a touch input of the driver DV.

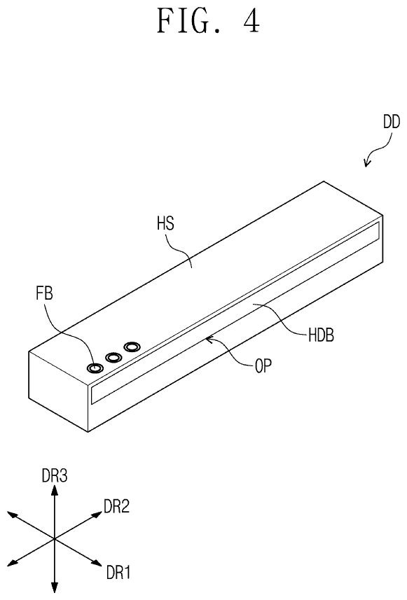

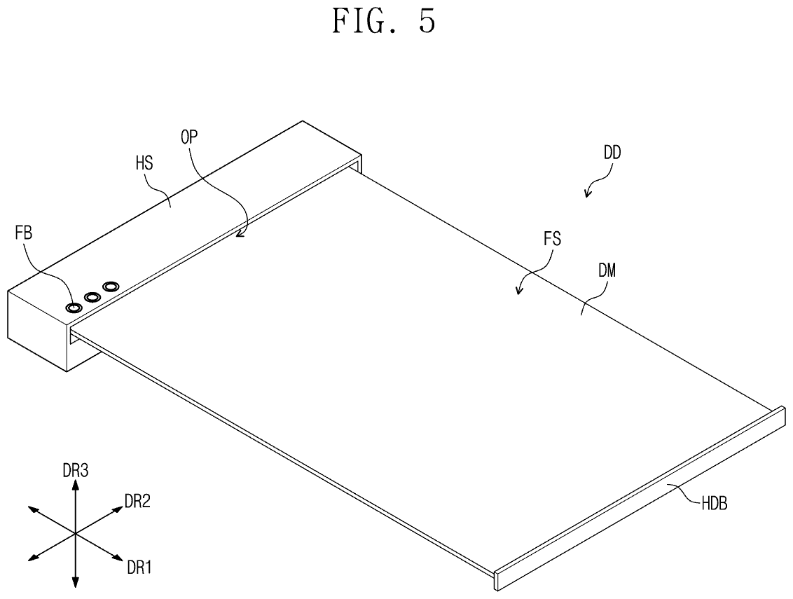

The display device DD according to an embodiment of the inventive concept may expand and contract in a first direction DR1 according to functional manipulation of the driver DV. For example, the display device DD may be a rollable display device. A rollable display device DD may include a housing (hereinafter, illustrated in FIGS. 4 and 5) and a display module (hereinafter, illustrated in FIG. 5) having flexibility and being pulled into or pulled out from the housing. In case that the display device DD is expanded in the first direction DR1, the image may be provided to the driver DV.

Hereinafter, a direction substantially perpendicularly crossing (or intersecting) a plane defined by the first direction DR1 and a second direction DR2 is defined as a third direction DR3. Also, as used herein, a meaning of being in a plan view is defined as being viewed in the third direction DR3.

By way of example, the display device DD for a vehicle is illustrated, but an embodiment of the inventive concept is not limited thereto. For example, the display device DD according to an embodiment of the inventive concept may also be used in an electronic apparatus such as a smartphone, a digital camera, a laptop, a monitor, and a smart television, which provides an image to a user.

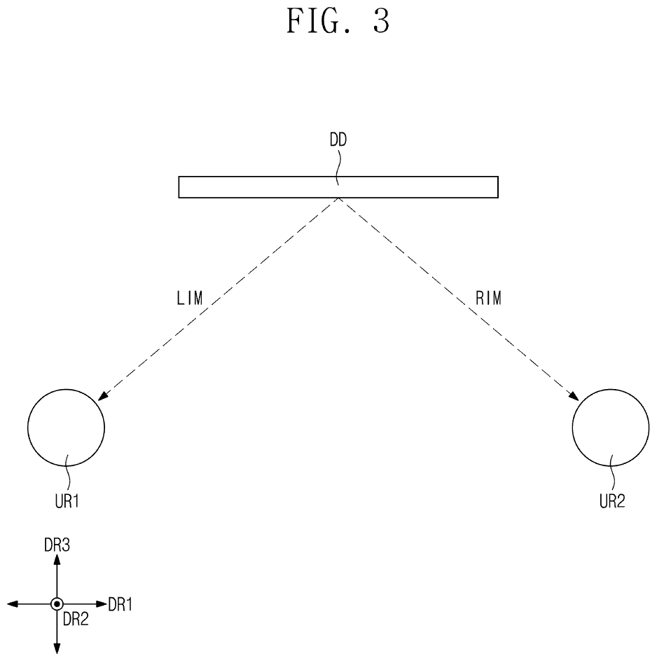

FIG. 3 is a schematic diagram illustrating that an image generated from the display device in FIGS. 1 and 2 is provided to users.

Referring to FIG. 3, the display device DD may be expanded and unrolled flat. Users UR1 and UR2 may be disposed to face the display device DD. A surface of the display device DD that the users UR1 and UR2 face may be a front surface of the display device DD. The front surface of the display device DD may be defined as a display surface of the display device DD.

The users UR1 and UR2 may include a first user UR1 and a second user UR2. The first user UR1 may be defined as the driver DV described above. The second user UR2 may be defined as a passenger in a passenger seat. When facing the display device DD, the first user UR1 and the second user UR2 may be respectively disposed on a left side and a right side.

In case that the display device DD is expanded, the display device DD may generate a dual image. For example, the display device DD may generate a first image LIM and a second image RIM. When facing the front surface of the display device DD, the first image LIM may be provided to a left side with respect to the display device DD, and the second image RIM may be provided to a right side with respect to the display device DD.

The first image LIM may be provided to the first user UR1. The second image RIM may be provided to the second user UR2. For example, the first user UR1 may be provided with a map image about a navigation through the first image LIM. The second user UR2 may watch a movie through the second image RIM.

Thus, the display device DD according to an embodiment of the inventive concept may generate a dual image in the vehicle AM, and provide the dual image to the first and second users UR1 and UR2 such as the driver DV and a passenger in a passenger seat.

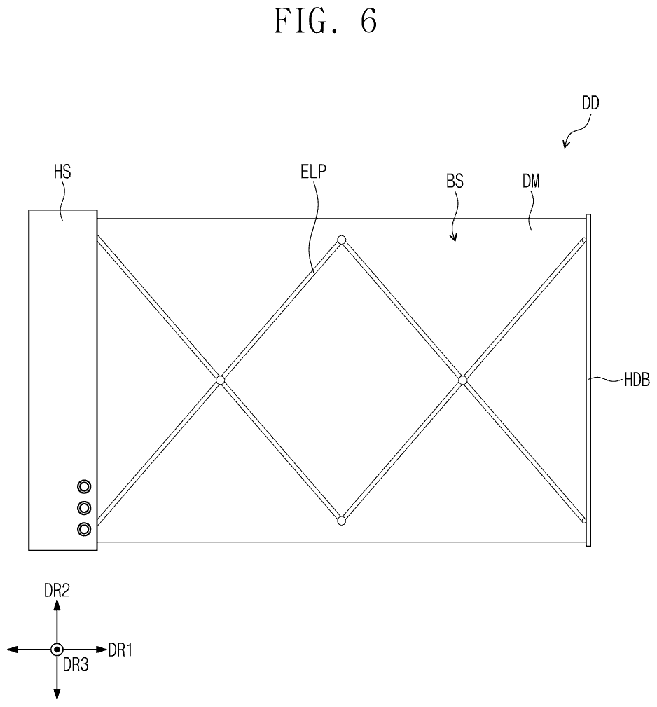

FIG. 4 is a schematic perspective view of a display device according to an embodiment of the inventive concept. FIG. 5 is a diagram illustrating that the display device in FIG. 4 is in an expansion mode. FIG. 6 is a diagram illustrating a rear of a display device in the expansion mode in FIG. 5.

Referring to FIGS. 4 and 5, a display device DD may include a housing HS, a head bar HDB, a display module DM, and one or more function buttons FB.

An opening OP that is open in a first direction DR1 may be defined in the housing HS. The housing HS may extend longer in a second direction DR2 than in the first direction DR1. Also, the housing HS may extend longer in the first direction DR1 than in a third direction DR3. However, the embodiments are not limited thereto, and various modifications may be made to the shape of the display device DD within the spirit and scope of the disclosure.

The head bar HDB may be disposed in the opening OP. The head bar HDB may move away from or toward the housing HS in the first direction DR1.

The display module DM may be a flexible display module. While being rolled or unrolled similar to a scroll, the display module DM may be pulled into or pulled out from the housing HS. For example, the display module DM may be wound and disposed inside the housing HS as illustrated in FIG. 4. Also, the display module DM may be unwound and disposed outside the housing HS as illustrated in FIG. 5.

A side of the display module DM with respect to the first direction DR1 may be connected to the head bar HDB. The display module DM may be moved in the first direction DR1 using the head bar HDB.

In case that the head bar HDB moves away from the housing HS in the first direction DR1, the display module DM may be pulled out from the housing HS through the opening OP as illustrated in FIG. 5. Thus, the display module DM may be expanded to the outside of the housing HS and exposed to the outside of the housing HS. Such an operation may be defined as an expansion mode. A front surface FS of the display module DM may be exposed to the outside and an image may be provided to the users UR1 and UR2 described above.

On the contrary, if the head bar HDB moves toward the housing HS in the first direction DR1, the display module DM may be pulled into the housing HS through the opening OP as illustrated in FIG. 4. Thus, the display module DM may be disposed inside the housing HS and may not be exposed to the outside. Such an operation may be defined as a contraction mode.

The function buttons FB may be disposed on an upper surface of the housing HS. The function buttons FB may provide various functions to the display device DD. For example, by using the function buttons FB, the display module DM disposed inside the housing HS may be moved out of the housing HS, or the display module DM outside the housing HS may be moved into the housing HS. By using the function buttons FB, luminance, definition, and the like of an image displayed from the display module DM may be controlled.

Referring to FIG. 6, an elevating portion ELP may be disposed on a rear surface BS of the display module DM. The rear surface BS of the display module DM may be defined as a surface opposed to the front surface FS. The elevating portion ELP may have a foldable-type structure such as bellows. The elevating portion ELP may be expanded and contracted in a first direction DR1.

The elevating portion ELP may be connected to the head bar HDB and the housing HS on the rear surface BS of the display module DM. In case that the elevating portion ELP is contracted, the elevating portion ELP may be disposed inside the housing HS, and in case that the elevating portion ELP is expanded, the elevating portion ELP may be expanded to the outside of the housing HS.

According to contraction and expansion of the elevating portion ELP, the head bar HDB may move in the first direction DR1, and the display module DM may be pulled into or pulled out from the housing HS. The elevating portion ELP may serve to support the display module DM expanded flat.

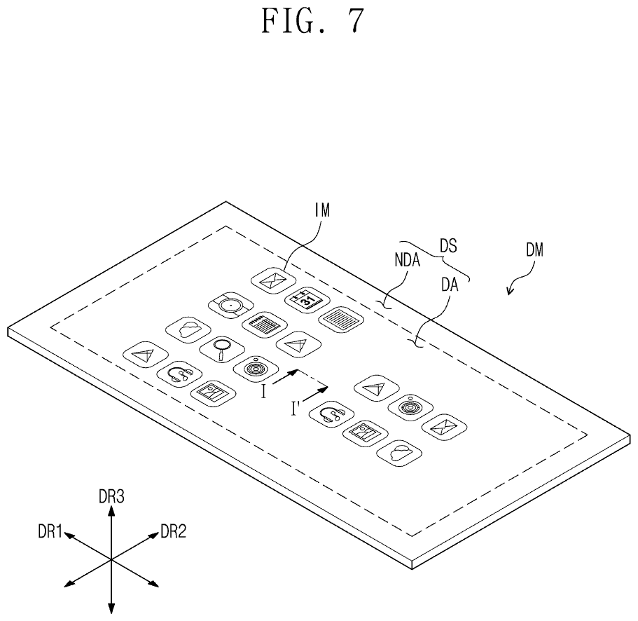

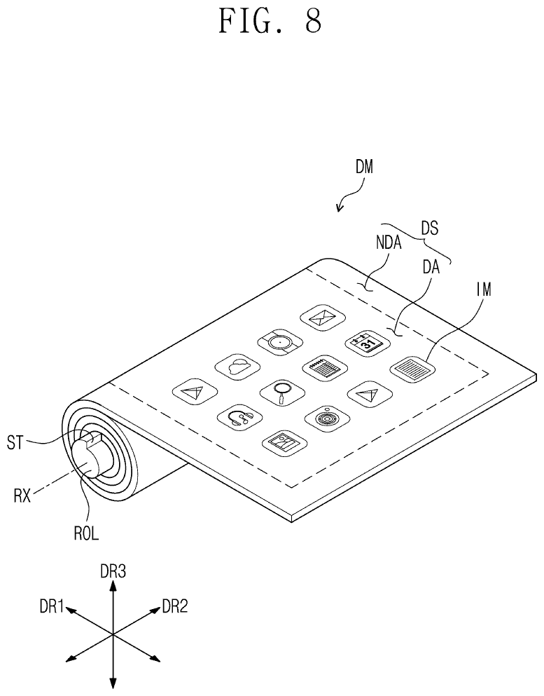

FIG. 7 is a schematic diagram illustrating the display module accommodated in the housing in FIGS. 4 and 5 in a flat state. FIG. 8 is a schematic diagram illustrating that a display module in FIG. 7 is wound.

Referring to FIGS. 7 and 8, the display module DM may have a plane defined by first and second directions DR1 and DR2. The display module DM may have a rectangular shape having long sides extending in the first direction DR1 and short sides extending in the second direction DR2. However, an embodiment of the inventive concept is not limited thereto, and the display module DM may have various shapes such as a circular shape or a polygonal shape.

The front surface FS of the display module DM described above may be defined as a display surface DS and have a plane defined by the first direction DR1 and the second direction DR2. Images IM generated from the display module DM may be provided to a user through the display surface DS.

The display surface DS may include a display region DA and a non-display region NDA around the display region DA. An image may be displayed in the display region DA, and an image may not be displayed in the non-display region NDA. The non-display region NDA may be adjacent to or surround the display region DA and define an edge of the display module DM printed in a color (e.g., in a predetermined or selectable color).

The display module DM may be rolled in the first direction DR1. The display module DM may be rolled so that the display surface DS faces the outside.

Another side of the display module DM opposed to a side of the display module DM connected to the head bar HDB may be connected to a roller ROL. Another side of the display module DM may be connected to a stepped portion ST of the roller ROL which is formed to have a step. The roller ROL may be disposed inside the housing HS. The roller ROL may rotate in clockwise and anti-clockwise directions with respect to a rotating axis RX extending in the second direction DR2.

According to rotation of the roller ROL, the display module DM may be wound on or unwound from the roller ROL. For example, in case that the roller ROL rotates in the anti-clockwise direction, the display module DM may be wound on the roller ROL. In case that the roller ROL rotates in the clockwise direction, the display module DM may be unwound from the roller ROL.

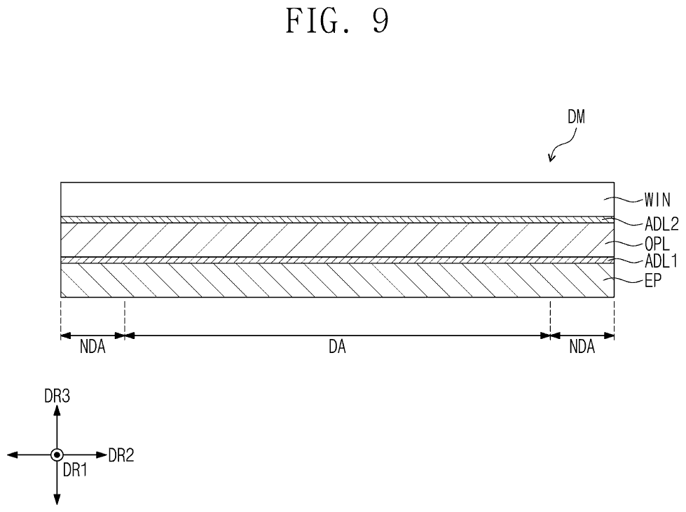

FIG. 9 is a schematic diagram of a cross section of the display module in FIG. 7.

By way of example, FIG. 9 illustrates a cross section of the display module DM viewed in a first direction DR1.

Referring to FIG. 9, the display module DM may include an electronic panel EP, an optical layer OPL, and/or a window WIN. The optical layer OPL may be disposed on the electronic panel EP, and the window WIN may be disposed on the optical layer OPL.

The electronic panel EP may generate the first and second images LIM and RIM, sense an external input, and reduce a reflectance for external light. A detailed configuration of the electronic panel EP will be described below in detail with reference to FIG. 10.

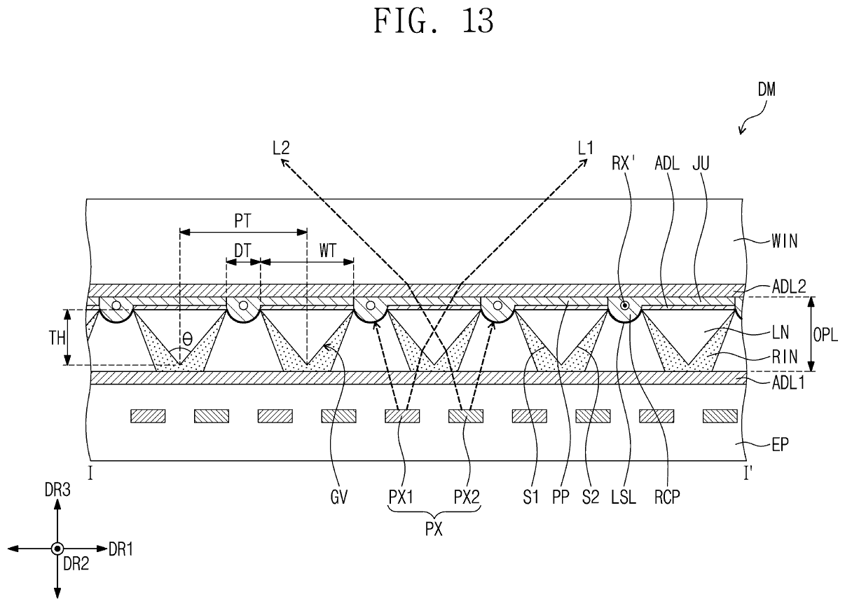

The optical layer OPL may refract the first and second images LIM and RIM generated from the electronic panel EP and respectively provide the refracted first and second images LIM and RIM to the first and second users UR1 and UR2. The first image LIM may be refracted at the optical layer OPL and provided to the first user UR1. The second image RIM may be refracted at the optical layer OPL and provided to the second user UR2. The optical layer OPL may serve to support the electronic panel EP. A more detailed configuration of the optical layer OPL will be described below in detail with reference to a cross-sectional view of FIG. 13.

The window WIN may be disposed on the optical layer OPL. The window WIN may protect the optical layer OPL and the electronic panel EP from an external scratch and impact. The window WIN may include, for example, glass or a transparent plastic material.

A first adhesive layer ADL1 may be disposed between the electronic panel EP and the optical layer OPL. The electronic panel EP and the optical layer OPL may be bonded to each other through the first adhesive layer ADL1. A second adhesive layer ADL2 may be disposed between the optical layer OPL and the window WIN. The optical layer OPL and the window WIN may be bonded to each other through the second adhesive layer ADL2.

The first adhesive layer ADL1 and the second adhesive layer ADL2 may include, for example, an optically clear adhesive (OCA) or a pressure sensitive adhesive (PSA).

FIG. 10 is a schematic cross-sectional view of an electronic panel showing a configuration of the electronic panel in FIG. 9.

By way of example, FIG. 10 illustrates a cross section of an electronic panel EP viewed in a first direction DR1.

Referring to FIG. 10, the electronic panel EP may include a display panel DP, an input sensing unit (or input sensing part) ISP disposed on the display panel DP, and/or an anti-reflective layer RPL disposed on the input sensing unit ISP. The display panel DP may be a flexible display panel. For example, the display panel DP may include a flexible substrate and a plurality of elements disposed on the flexible substrate.

The display panel DP according to an embodiment of the inventive concept may be an emissive display panel, but is not particularly limited. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include a quantum dot, a quantum rod, etc. Hereinafter, the display panel DP will be described as an organic light-emitting display panel.

The input sensing unit ISP may include one or more sensor units (or sensors) (not illustrated) for sensing an external input. By way of example, the input sensing unit ISP may sense an external input by using a capacitive method, but a sensing method of the input sensing unit ISP is not limited thereto. When the electronic panel EP is manufactured, the input sensing unit ISP may be formed directly on the display panel DP.

The anti-reflective layer RPL may be disposed on the input sensing unit ISP. When the electronic panel EP is manufactured, the anti-reflective layer RPL may be formed directly on the input sensing unit ISP. The anti-reflective layer RPL may be defined as a film for preventing external light reflection. The anti-reflective layer RPL may reduce a reflectance for external light incident onto the display panel DP from above a display device DD.

In case that external light travelling toward the display panel DP is reflected from the display panel DP and provided back to an external user, similar a mirror, the user may visually recognize the external light. To prevent such a phenomenon, by way of example, the anti-reflective layer RPL may include one or more color filters that display the same color as that of pixels of the display panel DP.

The color filters may filter external light to the same color as that of the pixels. In such a case, the external light may not be visually recognized by a user. However, an embodiment of the inventive concept is not limited thereto, and the anti-reflective layer RPL may include a retarder and/or a polarizer to reduce reflectance for external light.

By way of example, the input sensing unit ISP may be formed directly on the display panel DP, and the anti-reflective layer RPL may be formed directly on the input sensing unit ISP, but an embodiment of the inventive concept is not limited thereto. For example, the input sensing unit ISP may be separately manufactured and attached to the display panel DP through an adhesive layer, and the anti-reflective layer RPL may be separately manufactured and attached to the input sensing unit ISP through an adhesive layer.

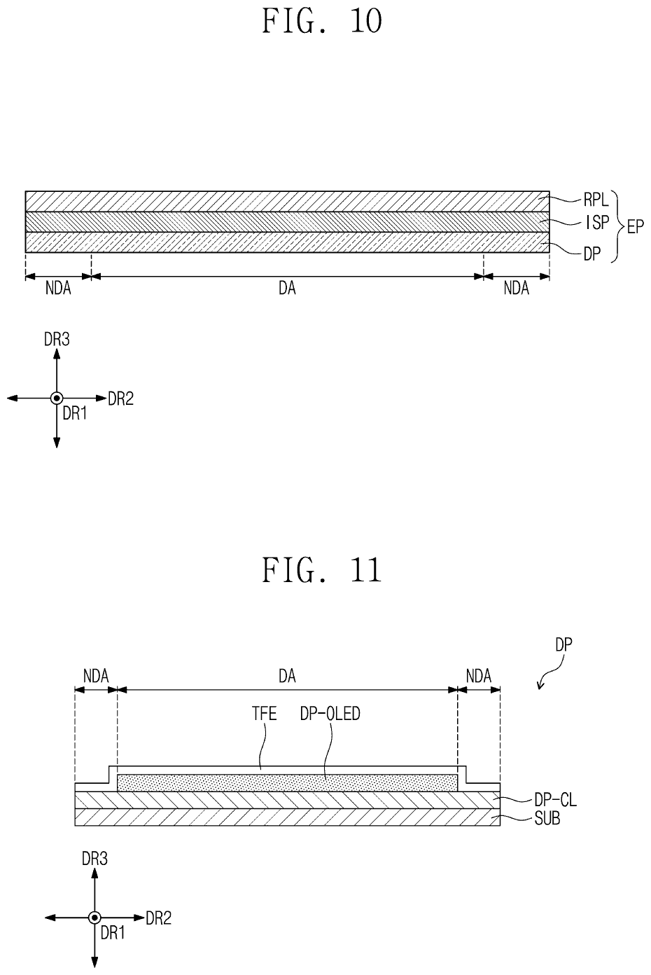

FIG. 11 is a schematic cross-sectional view of a display panel showing a configuration of the display panel in FIG. 10.

By way of example, FIG. 11 illustrates a cross section of a display panel DP viewed in a first direction DR1.

Referring to FIG. 11, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include a flexible plastic material such as polyimide. The display element layer DP-OLED may be disposed in the display region DA.

Pixels may be disposed in the display region DA. Each of the pixels may include a light-emitting element disposed in the display element layer DP-OLED and connected to a transistor disposed in the circuit element layer DP-CL.

The thin-film encapsulation layer TFE may be disposed on the circuit-element layer DP-CL and cover (or overlap) the display element layer DP-OLED. The thin-film encapsulation layer TFE may include inorganic layers and an organic layer between the inorganic layers. The inorganic layers may protect the pixels from moisture/oxygen. The organic layer may protect pixels from foreign substances such as dust particles.

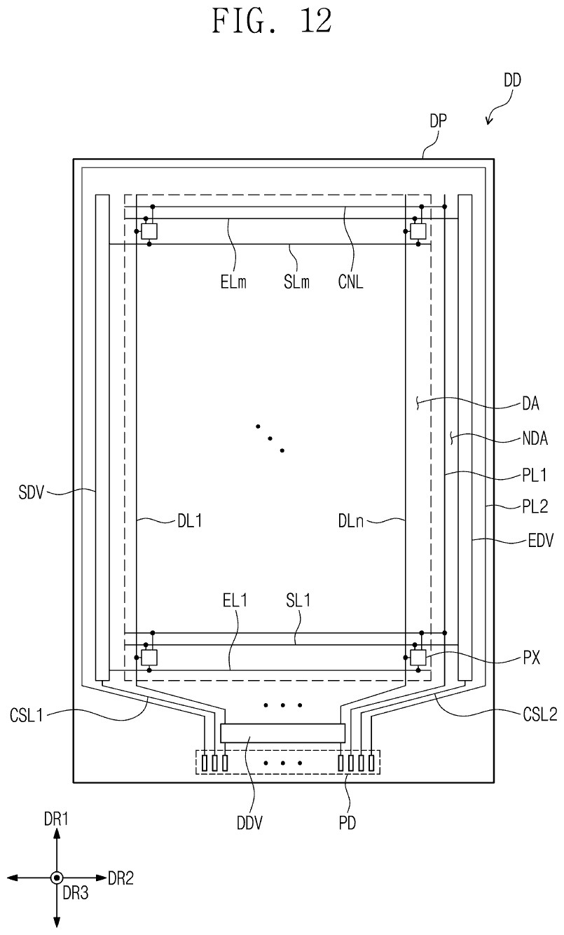

FIG. 12 is a schematic plan view of the display panel in FIG. 11.

Referring to FIG. 12, a display device DD may include the display panel DP, a scan driver SDV, a data driver DDV, a light emission driver EDV, and pads PD.

In an embodiment, the display panel DP may have a rectangular shape having long sides extending in a first direction DR1 and short sides extending in a second direction DR2, but a shape of the display panel DP is not limited thereto. The display panel DP may include a display region DA and a non-display region NDA surrounding or adjacent to the display region DA.

The display panel DP may include pixels PX, scan lines SL1 to SLm, data lines DL1 to DLn, emission lines EL1 to ELm, first and second control lines CSL1 and CSL2, first and second power lines PL1 and PL2, and connection lines CNL. m and n are natural numbers.

The pixels PX may be disposed in the display region DA. The pixels PX may display red, green, and blue. The scan driver SDV and the light emission driver EDV may be disposed in sections of the non-display region NDA respectively adjacent to the long sides of the display panel DP. The data driver DDV may be disposed in the non-display region NDA adjacent to any one of the short sides of the display panel DP. In a plan view, the data driver DDV may be adjacent to a lower end of the display panel DP.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The emission lines EL1 to ELm may extend in the second direction DR2 and may be connected to the pixels PX and the light emission driver EDV.

The first power line PL1 may extend in the first direction DR1 and may be disposed in the non-display region NDA. The first power line PL1 may be disposed between the display region DA and the light emission driver EDV.

The connection lines CNL may extend in the second direction DR2 and may be arranged in the first direction DR1 and connected to the first power line PL1 and the pixels PX. A first voltage may be applied to the pixels PX through the connection lines CNL and the first power line PL1 connected to each other.

The second power line PL2 may be disposed in the non-display region NDA and extend along the long sides of the display panel DP and another short side of the display panel DP on which the data driver DDV is not disposed. The second power line PL2 may be disposed on a further outward side than the scan driver SDV and the light emission driver EDV.

Although not illustrated, the second power line PL2 may extend toward the display region DA and may be connected to the pixels PX. A second voltage having a lower level than the first voltage may be applied to the pixels PX through the second power line PL2.

The first control line CSL1 may be connected to the scan driver SDV and extend toward the lower end of the display panel DP. The second control line CSL2 may be connected to the light emission driver EDV and extend toward the lower end of the display panel DP. The data driver DDV may be disposed between the first control line CSL1 and the second control line CSL2.

The pads PD may be disposed in the non-display region NDA adjacent to the lower end of the display panel DP and more adjacent to the lower end of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling an operation of the scan driver SDV, the data driver DDV, and the light emission driver EDV, and a voltage generator for generating first and second voltages. The timing controller and the voltage generator may be connected to the pads PD through a printed circuit board.

The scan driver SDV may generate scan signals, and the scan signals may be applied to the pixels PX through the scan lines SL1 to SLm. The data driver DDV may generate data voltages, and the data voltages may be applied to the pixels PX through the data lines DL1 to DLn. The light emission driver EDV may generate emission signals, and the emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals.

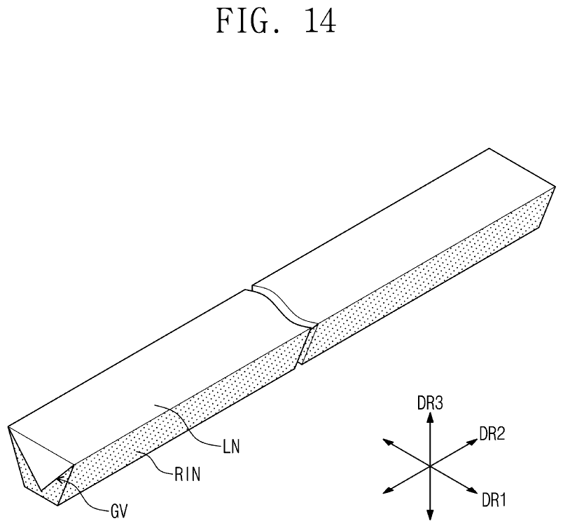

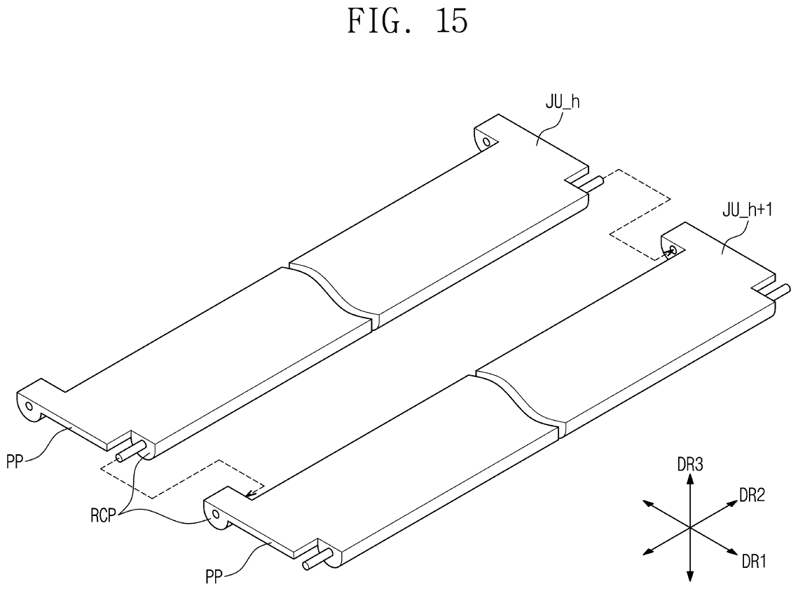

FIG. 13 is a schematic cross-sectional view taken along line I-I′ in FIG. 7. FIG. 14 is a schematic perspective view of any one lens and resin layer in FIG. 13. FIG. 15 is an exploded perspective view of an h-th joint unit and an (h+1)-th joint unit, which are adjacent to each other, among joint units in FIG. 13.

FIG. 13 is substantially a diagram for describing a detailed configuration of the optical layer OPL, and for convenience of description, schematically illustrates the electronic panel EP as including only pixels PX.

Referring to FIGS. 13, 14, and 15, the pixels PX of the electronic panel EP may include first pixels PX1 and second pixels PX2. The first and second pixels PX1 and PX2 may be included in the display panel DP described above. The first pixels PX1 and the second pixels PX2 may be disposed alternately in a first direction DR1.

The optical layer OPL and the window WIN may be sequentially disposed on the electronic panel EP. The first adhesive layer ADL1 and the second adhesive layer ADL2 may be respectively disposed between the electronic panel EP and the optical layer OPL and between the optical layer OPL and the window WIN.

The optical layer OPL may include lenses LN, resin layers RIN, and/or joint units (or joint parts) JU. The lenses LN may be disposed on the electronic panel EP. The resin layers RIN may be respectively disposed under the lenses LN between the lenses LN and the electronic panel EP. The joint units JU may be respectively disposed on the lenses LN between the window WIN and the electronic panel EP.

The lenses LN may be arranged in the first direction DR1 and extend in a second direction DR2. When viewed in the second direction DR2, the lenses LN may each have a shape of an inverted triangle. In an embodiment, the lenses LN may include transparent metal. For example, the lenses LN may include aluminum oxynitride.

Knoop hardness of the lenses LN may be about 1500 kg/mm² to about 2500 kg/mm². The lenses LN may be harder than the resin layers RIN. The lenses LN may have greater elastic modulus than the resin layers RIN.

Grooves GV may be respectively defined in the resin layers RIN to face the lenses LN. The lenses LN may be respectively disposed in the grooves GV. Surfaces of the resin layers RIN defining the grooves GV may be defined as recessed surfaces.

Although not illustrated, an adhesive layer may be disposed between the lenses LN and the recessed surfaces of the resin layers RIN defining the grooves GV, and through the adhesive layer, the lenses LN may be attached to the resin layers RIN. The adhesive layer may include an optically clear adhesive or a pressure sensitive adhesive.

The resin layers RIN may have a flexible property. For example, the resin layers RIN may include a silicone resin. Similar to the lenses LN, the resin layers RIN may be arranged in the first direction DR1 and extend in the second direction DR2. Two side surfaces of each of the lenses LN opposed to each other in the first direction DR1 may each have an inclined surface with respect to a third direction DR3. A distance between the two side surfaces of each of the lenses LN may gradually decrease in a downward direction.

The first adhesive layer ADL1 may be disposed between the electronic panel EP and the resin layers RIN. The electronic panel EP and the resin layers RIN may be bonded to each other through the first adhesive layer ADL1.

Similar to the lenses LN, the joint units JU may be arranged in the first direction DR1 and extend in the second direction DR2. In an embodiment, the joint units JU may include fiber reinforced plastic made of a transparent material.

The joint units JU may be disposed on the lenses LN and rotatably coupled to each other. For example, a side of an h-th joint unit JU_h and a side of an (h+1)-th joint unit JU_h+1 may be adjacent to each other and coupled to each other to rotate with respect to a rotating axis RX′ parallel to the second direction DR2. h is a natural number.

The side of the h-th joint unit JU_h and the side of the (h+1)-th joint unit JU_h+1 rotatably coupled to each other may be defined as a rotary coupling portion RCP. Each of rotary coupling portions RCP may be disposed between two adjacent lenses LN (for example, an h-th lens and an (h+1)-th lens). A lower portion of each of the rotary coupling portions RCP may have a downwardly convex curved surface.

The optical layer OPL may further include light blocking layers LSL. The light blocking layers LSL may be respectively disposed under the lower portions of the rotary coupling portions RCP. The light blocking layers LSL may be disposed between the lenses LN. The curved surfaces of the lower portions of the rotary coupling portions RCP may be coated with the light blocking layers LSL. The light blocking layers LSL may have a black color and block light.

The lenses LN may be respectively attached to the joint units JU. For example, adhesive layers ADL may be respectively disposed between the lenses LN and the joint units JU, and the lenses LN may be attached to the joint units JU through the adhesive layers ADL. The adhesive layers ADL may include an optically clear adhesive or a pressure sensitive adhesive.

Each of the joint units JU may include a flat portion PP adjacent to a side of each of the joint units JU. The lenses LN may be respectively attached to flat portions PP.

An h-th lens LN may be disposed under a flat portion PP of the h-th joint unit JU_h illustrated in FIG. 15 and attached to the flat portion PP of the h-th joint unit JU_h. An (h+1)-th lens LN may be disposed under a flat portion PP of the (h+1)-th joint unit JU_h+1 and attached to the flat portion PP of the (h+1)-th joint unit JU_h+1.

The window WIN may be disposed on the joint units JU, and the second adhesive layer ADL2 may be disposed between the window WIN and the joint units JU. The window WIN and the joint units JU may be bonded to each other through the second adhesive layer ADL2.

A refractive index of the lenses LN may be greater than a refractive index of the resin layers RIN. A refractive index of the window WIN may be smaller than the refractive index of the lenses LN. For example, the refractive index of the resin layers RIN may be about 1.44, the refractive index of the lenses LN may be about 1.64, and the refractive index of the window WIN may be about 1.5. The refractive index of the window WIN may be smaller than that of each of the second adhesive layer ADL2, the joint units JU, and the adhesive layers ADL.

With respect to a third direction DR3, a thickness TH of each of the lenses LN may be about 45 μm to about 55 μm. With respect to the first direction DR1, a width WT of an upper surface of each of the lenses LN may be about 60 μm to about 70 μm. An angle θ defined by a first side S1 and a second side S2 of each of the lenses LN oriented downward may be about 70 degrees to about 90 degrees.

With respect to the first direction DR1, a distance DT between two adjacent lenses LN may be about 30 μm to about 40 μm. With respect to the first direction DR1, a distance between central portions of two adjacent lenses LN may be defined as a pitch PT, and the pitch PT may be about 90 μm to about 110 μm.

A pair of a first pixel PX1 and a second pixel PX2 which are adjacent to each other may be disposed so that the first pixel PX1 and the second pixel PX2 are disposed on two sides of a corresponding lens LN, among the lenses LN, with respect to a central portion of the corresponding lens LN in a plan view. Specifically, among the pair of the first and second pixels PX1 and PX2, the first pixel PX1 may be disposed below a first side S1 of the corresponding lens LN, and the second pixel PX2 may be disposed below a second side S2 of the corresponding lens LN.

The first pixels PX1 may generate first light L1, and the second pixels PX2 may generate second light L2. The first light L1 and the second light L2 may be defined as light travelling toward the resin layers RIN.

The first light L1 may pass through the resin layers RIN toward the lenses LN. Since the lenses LN may have greater refractive index than the resin layers RIN, the first light L1 may be refracted rightward at the first sides S1. Since the window WIN may have relatively small refractive index, the first light L1 may further be refracted rightward at a lower surface of the window WIN. Part of light generated from the first pixels PX1 may travel leftward and may be blocked at the light blocking layers LSL.

Thus, light generated from the first pixels PX1 may be provided to a right side with respect to the display module DM and may not be provided to a left side with respect to the display module DM. The first light L1 may substantially display the first image LIM described above.

The second light L2 may pass through the resin layers RIN toward the lenses LN. Since the lenses LN may have greater refractive index than the resin layers RIN, the second light L2 may be refracted leftward at the second sides S2. Since the window WIN may have relatively small refractive index, the second light L2 may further be refracted leftward at the lower surface of the window WIN. Part of light generated from the second pixels PX2 may travel rightward and may be blocked at the light blocking layers LSL.

Thus, light generated from the second pixels PX2 may be provided to the left side with respect to the display module DM and may not be provided to the right side with respect to the display module DM. The second light L2 may display the second image RIM described above.

The light generated from the first pixels PX1 may be refracted further rightward as illustrated in FIG. 13, thereby providing the first image LIM in FIG. 3 to the first user UR1. The light generated from the second pixels PX2 may be refracted further leftward as illustrated in FIG. 13, thereby providing the second image RIM in FIG. 3 to the second user UR2.

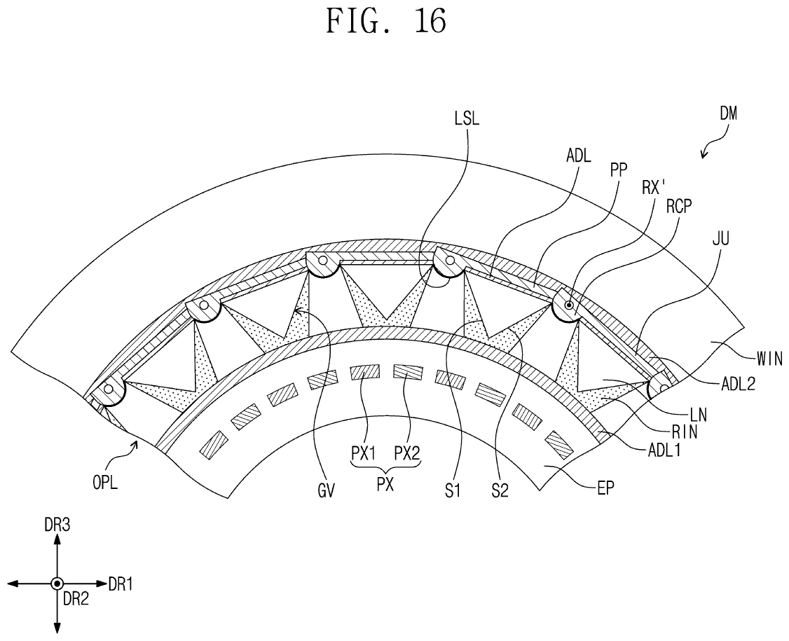

FIG. 16 is a schematic diagram illustrating that the display module in FIG. 13 is bent.

Referring to FIGS. 13 and 16, in case that the joint units JU are rotated with respect to each other and arranged in a form of a curve as illustrated in FIG. 16, the display module DM may be bent. In such a case, the display module DM may be wound on the roller ROL as illustrated in FIG. 8.

In case that the joint units JU are rotated and arranged flat as illustrated in FIG. 13, the display module DM may be unrolled flat. In such a case, the display module DM may be unwound from the roller ROL. Thus, according to rotation of the joint units JU, the electronic panel EP may be wound and unwound.

As described above, the lenses LN including transparent metal may have a relatively hard structure. The lenses LN may serve to support the display module DM flat which is unrolled flat. Also, the lenses LN may serve to support the electronic panel EP flat which is unrolled flat.

According to the configuration described above, in an embodiment of the inventive concept, in case that the rollable electronic panel EP is unwound, the lenses LN may support the electronic panel EP flat, and an image generated from the electronic panel EP may be dually provided to the users UR1 and UR2.

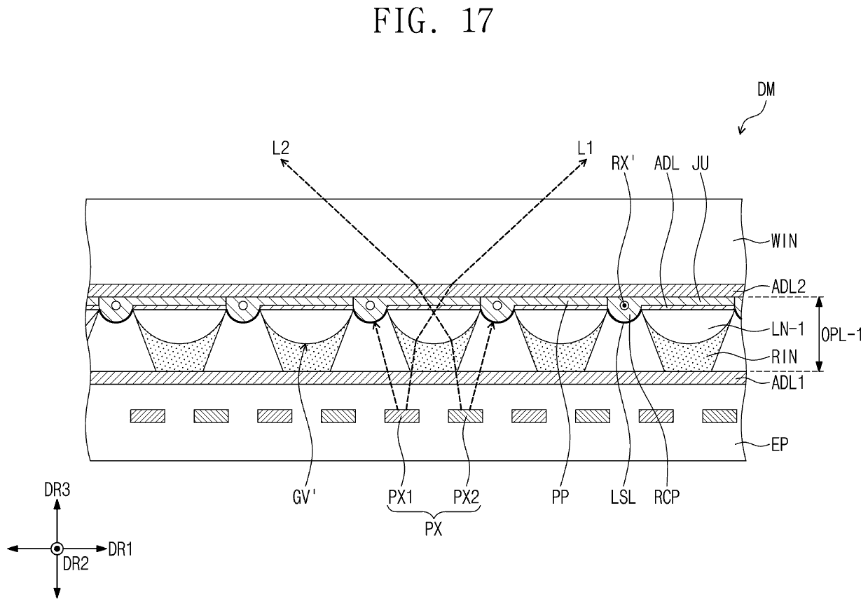

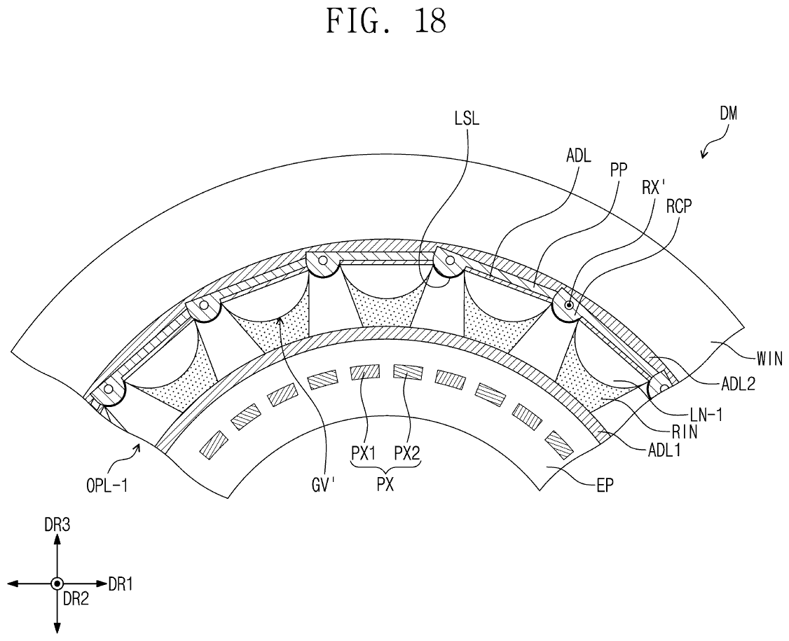

FIG. 17 is a schematic diagram showing a configuration of an optical layer according to another embodiment of the inventive concept. FIG. 18 is a schematic diagram illustrating that a display module in FIG. 17 is bent.

By way of example, FIGS. 17 and 18 are schematic cross-sectional views corresponding to FIGS. 13 and 16.

Hereinafter, description of a configuration of an optical layer OPL-1 in FIGS. 17 and 18, mainly focused on a configuration different from that of the optical layer OPL in FIGS. 13 and 16, will be made.

Referring to FIGS. 17 and 18, when viewed in a second direction DR2, lenses LN-1 of the optical layer OPL-1 may each have a downwardly convex shape. Grooves GV′ of resin layers RIN may each have a concave shape corresponding to the shape of each of the lenses LN-1. Other components of the optical layer OPL-1 may be substantially identical or similar to those of the optical layer OPL. According to rotation of joint units JU, a display module DM may be wound and unwound, and first light L1 and second light L2 may be substantially refracted as illustrated in FIG. 13.

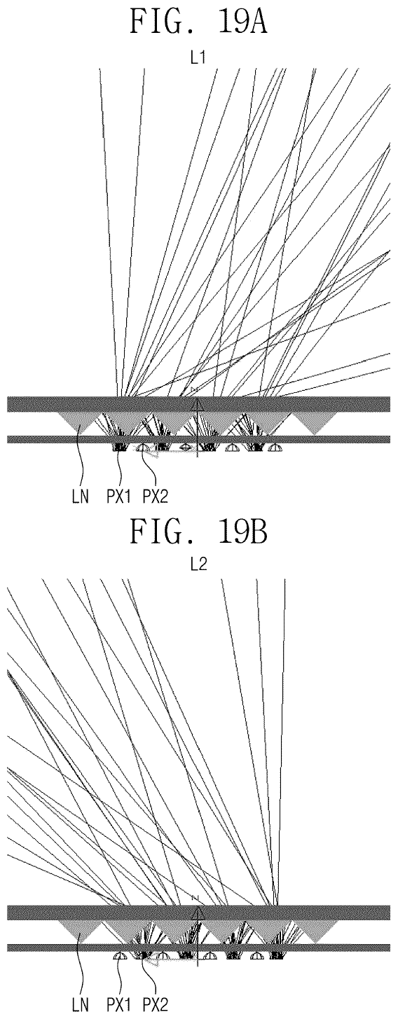

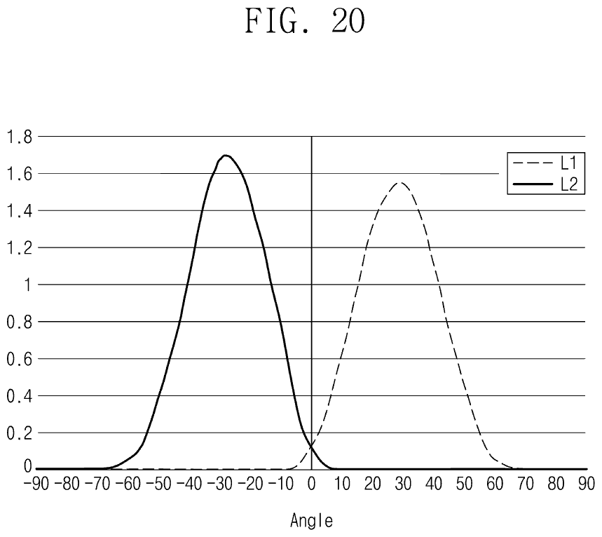

FIG. 19A is a schematic diagram illustrating refraction of first light by the lenses in FIG. 13 as a simulation result. FIG. 19B is a schematic diagram illustrating refraction of second light by the lenses in FIG. 13 as a simulation result. FIG. 20 is a schematic diagram illustrating luminance of the first light and the second light in FIGS. 19A and 19B as a simulation result.

Some components are omitted in FIGS. 19A and 19B, and the lenses LN and the first and second pixels PX1 and PX2 are mainly illustrated, and refraction of light by the lenses LN is mainly illustrated.

In FIG. 20, 0 degrees represent an angle of light travelling in a direction perpendicular to a plane of the display module DM, a negative angle represents an angle of light refracted leftward compared to 0 degrees, and a positive angle represents an angle of light refracted rightward compared to 0 degrees. A unit of luminance in FIG. 20 may be cd/m².

Referring to FIGS. 19A and 20, light generated from the first pixels PX1 may be mostly refracted rightward by the lenses LN, and thus luminance of first light L1 travelling toward a right side from the display module DM may be high. Accordingly, the first light L1 may be provided so as to become brighter toward a right side with respect to the display module DM. As a result, the first light L1 may be provided to a user disposed on a right side with respect to the display module DM.

Referring to FIGS. 19B and 20, light generated from the second pixels PX2 may be mostly refracted leftward by the lenses LN, and thus luminance of second light L2 travelling toward a left side from the display module DM may be high. Accordingly, the second light L2 may be provided so as to become brighter toward a left side with respect to the display module DM. As a result, the second light L2 may be provided to a user disposed on a left side with respect to the display module DM.

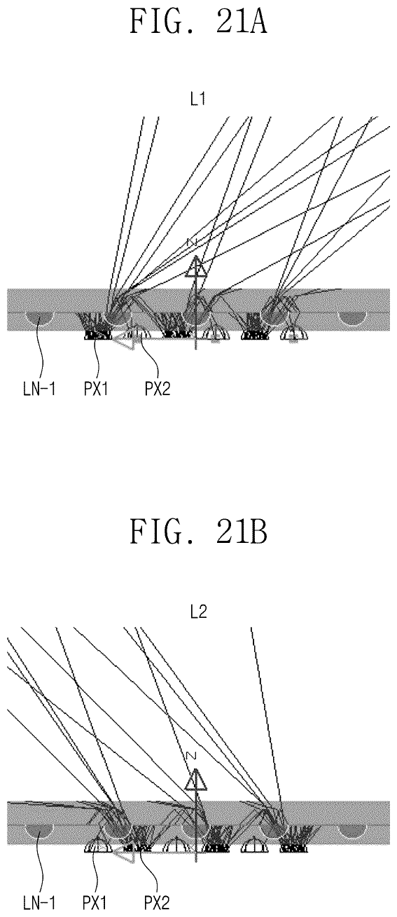

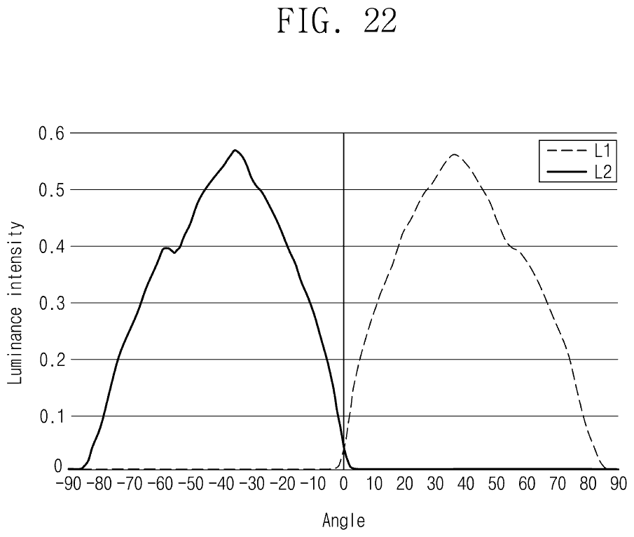

FIG. 21A is a schematic diagram illustrating refraction of first light by the lenses in FIG. 17 as a simulation result. FIG. 21B is a schematic diagram illustrating refraction of second light by the lenses in FIG. 17 as a simulation result. FIG. 22 is a schematic diagram illustrating luminance of the first light and the second light in FIGS. 21A and 21B as a simulation result.

Some components are omitted in FIGS. 21A and 21B, and the lenses LN-1 and first and second pixels PX1 and PX2 are mainly illustrated, and refraction of light by the lenses LN-1 is mainly illustrated.

Referring to FIGS. 21A, 21B, and 22, light generated from the first pixels PX1 may be mostly refracted rightward by the lenses LN-1, and thus luminance of first light L1 travelling toward a right side from the display module DM may be high. Light generated from the second pixels PX2 may be mostly refracted leftward by the lenses LN-1, and thus luminance of second light L2 travelling toward a left side from the display module DM may be high.

Thus, in case that the lenses LN-1 are used in the same manner as the lenses LN, the first light L1 and the second light L2 may be respectively provided to users disposed on a right side and a left side with respect to the display module DM.

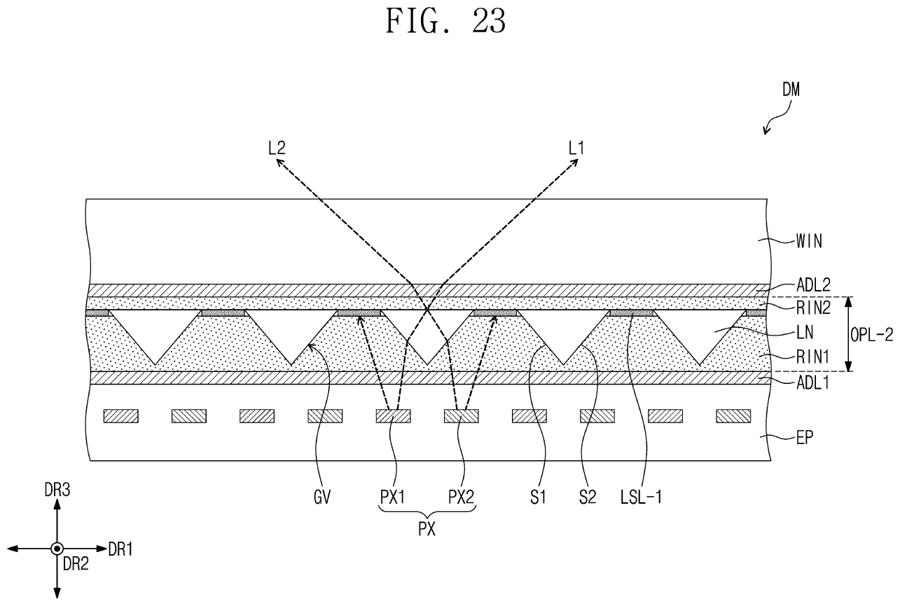

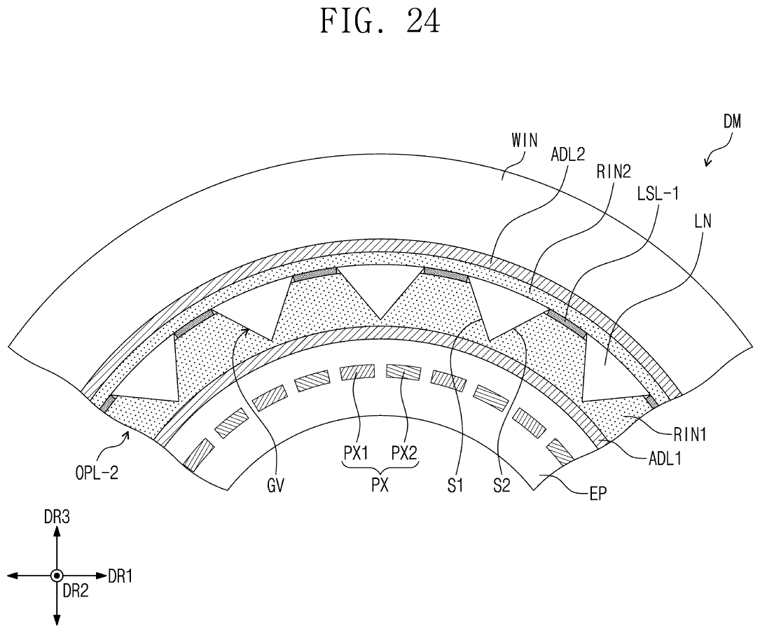

FIG. 23 is a schematic diagram showing a configuration of an optical layer according to another embodiment of the inventive concept. FIG. 24 is a schematic diagram illustrating that a display module in FIG. 23 is bent.

By way of example, FIGS. 23 and 24 are schematic cross-sectional views corresponding to FIGS. 13 and 16.

Hereinafter, description of a configuration of an optical layer OPL-2 in FIGS. 23 and 24, mainly focused on a configuration different from that of the optical layer OPL in FIGS. 13 and 16, will be made.

Referring to FIGS. 23 and 24, the optical layer OPL-2 may include lenses LN, light blocking layers LSL-1, a first resin layer RIN1, and a second resin layer RIN2. The light blocking layers LSL-1 may be disposed between the lenses LN. The first resin layer RIN1 may be disposed between the lenses LN and an electronic panel EP and between the light blocking layers LSL-1 and the electronic panel EP.

The lenses LN may be disposed in grooves GV defined in the first resin layer RIN1. The light blocking layers LSL-1 may be disposed on upper surfaces of the first resin layer RIN1 between the grooves GV. Upper surfaces of the light blocking layers LSL-1 and upper surfaces of the lenses LN may be disposed on the same plane.

A first adhesive layer ADL1 may be disposed between the first resin layer RIN1 and the electronic panel EP. The first resin layer RIN1 and the electronic panel EP may be bonded to each other through the first adhesive layer ADL1.

The second resin layer RIN2 may be disposed on the lenses LN and the light blocking layers LSL-1. A window WIN may be disposed on the second resin layer RIN2, and a second adhesive layer ADL2 may be disposed between the window WIN and the second resin layer RIN2. The window WIN and the second resin layer RIN2 may be bonded to each other through the second adhesive layer ADL2. The first and second resin layers RIN1 and RIN2 may include the same material. For example, the first and second resin layers RIN1 and RIN2 may include a silicone resin.

As described above, the lenses LN may refract first light L1 and second light L2. Similar to the light blocking layers LSL described above, the light blocking layers LSL-1 may block light travelling leftward from first pixels PX1 and light travelling rightward from second pixels PX2.

As described above, according to rotation of joint units JU, a display module DM may be wound and unwound.

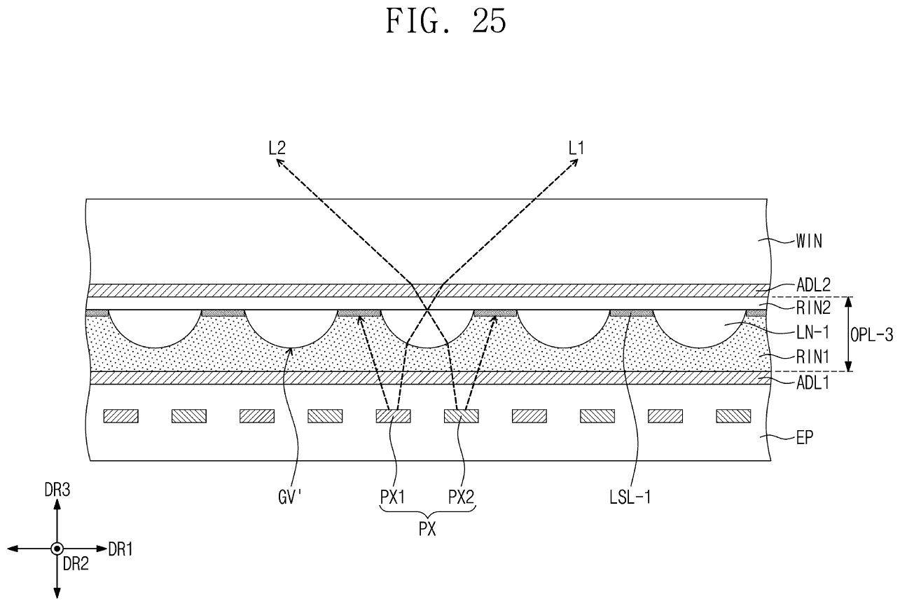

FIG. 25 is a schematic diagram showing a configuration of an optical layer according to another embodiment of the inventive concept.

By way of example, FIG. 25 is a cross-sectional view corresponding to FIG. 23, and a drawing illustrating that a display module DM in FIG. 25 is bent is omitted.

Referring to FIG. 25, lenses LN-1 of an optical layer OPL-3 may each have a downwardly convex curved surface, and other components of the optical layer OPL-3 may be substantially identical or similar to those of the optical layer OPL-2 in FIG. 23.

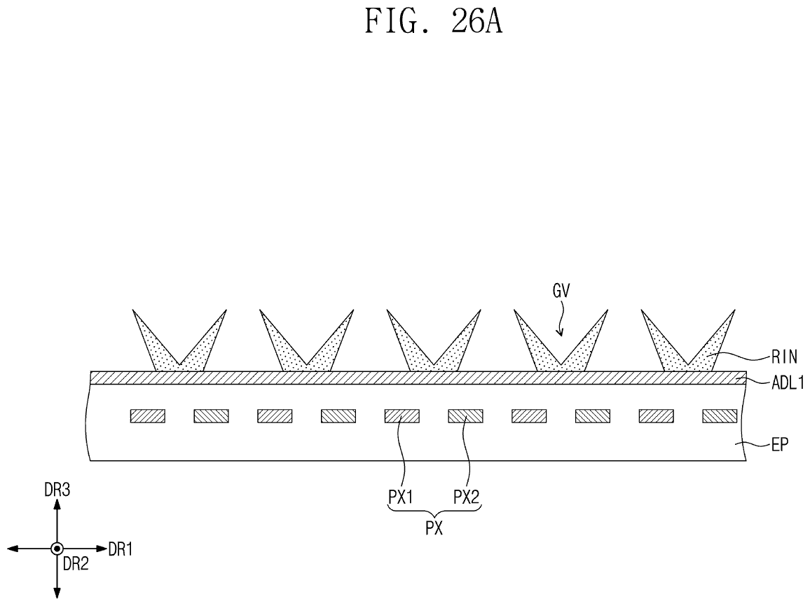

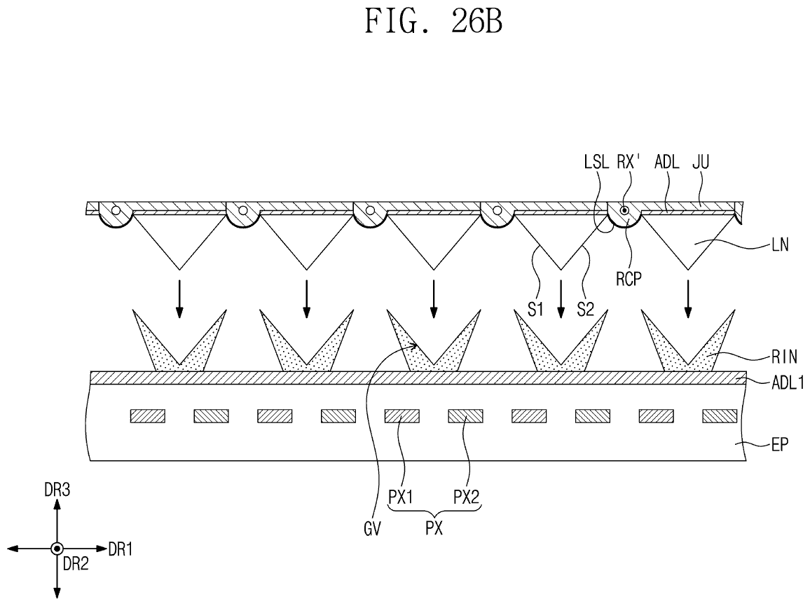

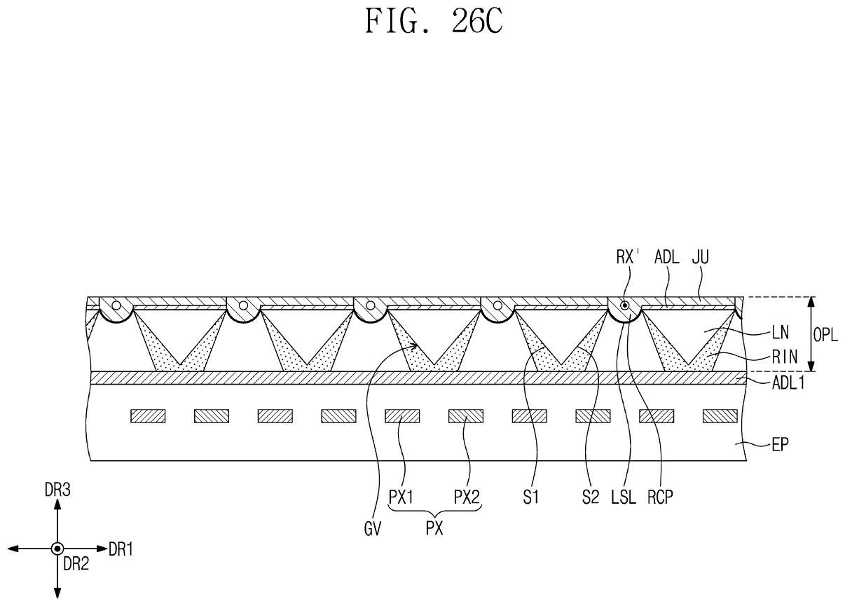

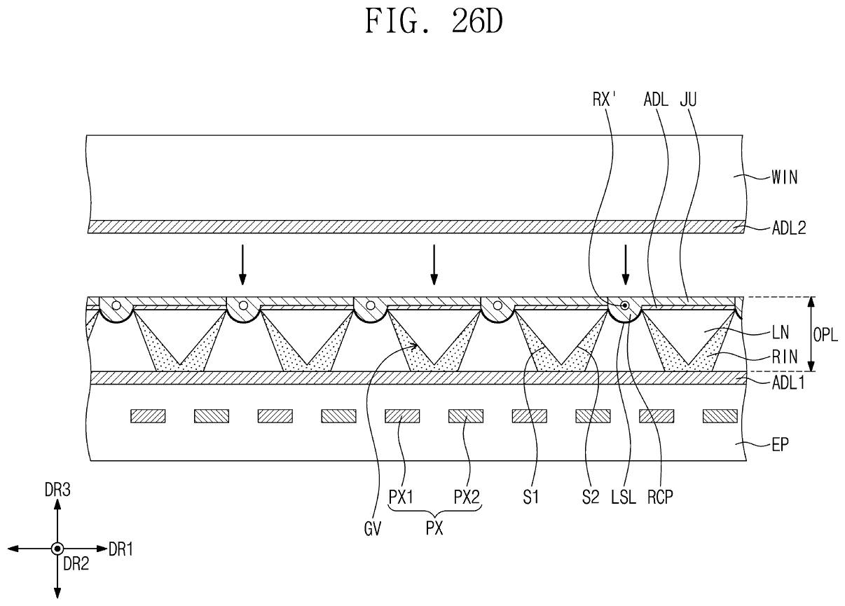

FIGS. 26A to 26D are schematic diagrams for describing a method of manufacturing the display module in FIG. 13.

By way of example, FIGS. 26A to 26D are cross-sectional views corresponding to FIG. 13.

Referring to FIG. 26A, an electronic panel EP may be prepared, and resin layers RIN having grooves GV defined therein may be provided on the electronic panel EP. The resin layers RIN may be arranged at substantially equal intervals in a first direction DR1. Each of the resin layers RIN may be disposed on a corresponding pair of a first pixel PX1 and a second pixel PX2 among first and second pixels PX1 and PX2.

Referring to FIG. 26B, lenses LN and joint units JU may be provided on the resin layers RIN. The lenses LN and the joint units JU may be provided on the resin layers RIN while being bonded to each other through adhesive layers ADL. The lenses LN may be disposed and aligned on the resin layers RIN.

Referring to FIG. 26C, the lenses LN may be respectively provided in the grooves GV and attached to the resin layers RIN. Thus, the optical layer OPL in FIG. 13 may be manufactured. Although not illustrated, the optical layer OPL-1 in FIG. 17 may also be manufactured in a similar manner to that for manufacturing the optical layer OPL.

Referring to FIG. 26D, a window WIN may be provided on the optical layer OPL, and the display module DM in FIG. 13 may thus be manufactured.

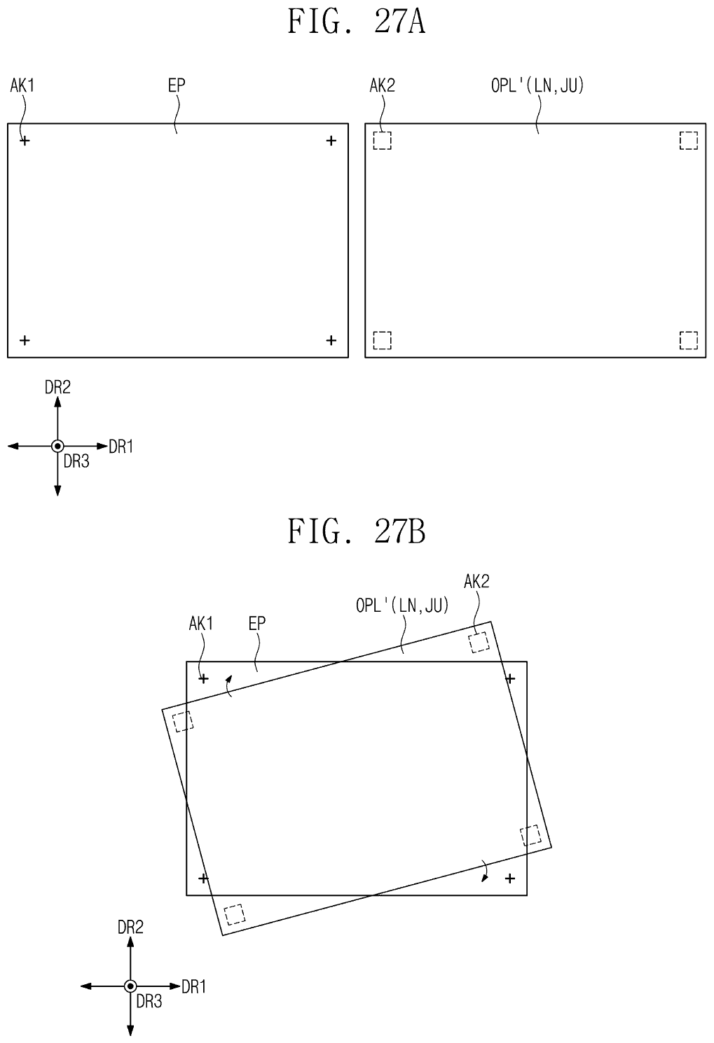

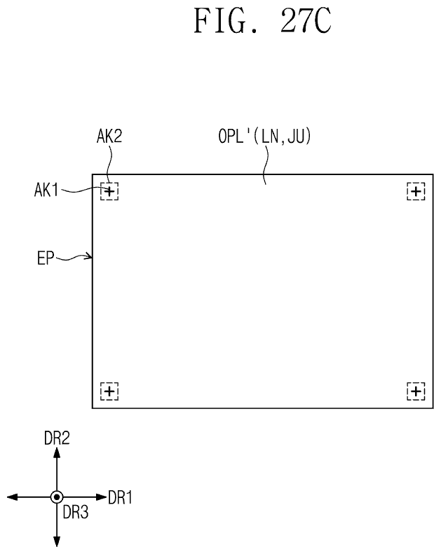

FIGS. 27A to 27C are schematic diagrams for describing a method of aligning an optical layer and an electronic panel.

Referring to FIGS. 26A, 26B, and 27A, an electronic panel EP and an optical layer OPL′ may be prepared. The electronic panel EP may correspond to the structure illustrated in FIG. 26A. For example, the electronic panel EP may be prepared in a state in which the resin layers RIN in FIG. 26A are disposed thereon. The optical layer OPL′ may correspond to the structure illustrated in FIG. 26B. For example, the optical layer OPL′ may be prepared in a state of including only the joint units JU and the lenses LN in FIG. 26B.

First alignment marks AK1 may be defined in the electronic panel EP. The first alignment marks AK1 may be respectively adjacent to four corners of the electronic panel EP. By way of example, the first alignment marks AK1 may each have a cross shape, but a shape of each of the first alignment marks AK1 is not limited thereto.

Second alignment marks AK2 may be defined in the optical layer OPL′. The second alignment marks AK2 may be respectively adjacent to four corners of the optical layer OPL′. By way of example, the second alignment marks AK2 may each be formed with dots disposed in a quadrangular shape, but a shape of each of the second alignment marks AK2 is not limited thereto.

Referring to FIGS. 27B and 27C, the optical layer OPL′ may be disposed on the electronic panel EP. The optical layer OPL′ may be aligned to overlap the electronic panel EP through the first alignment marks AK1 and the second alignment marks AK2.

As illustrated in FIG. 27B, the optical layer OPL′ may be misaligned with the electronic panel EP. For example, the first alignment marks AK1 may deviate from the second alignment marks AK2.

As illustrated in FIG. 27C, the first alignment marks AK1 may be respectively disposed in the second alignment marks AK2, so that the optical layer OPL′ may be aligned with the electronic panel EP. For example, after the location of the first alignment marks AK1 and the second alignment marks AK2 is identified through a vision camera (not illustrated), the optical layer OPL′ may be moved so that the first alignment marks AK1 are respectively disposed in the second alignment marks AK2. The optical layer OPL′ may be moved and aligned with the electronic panel EP.

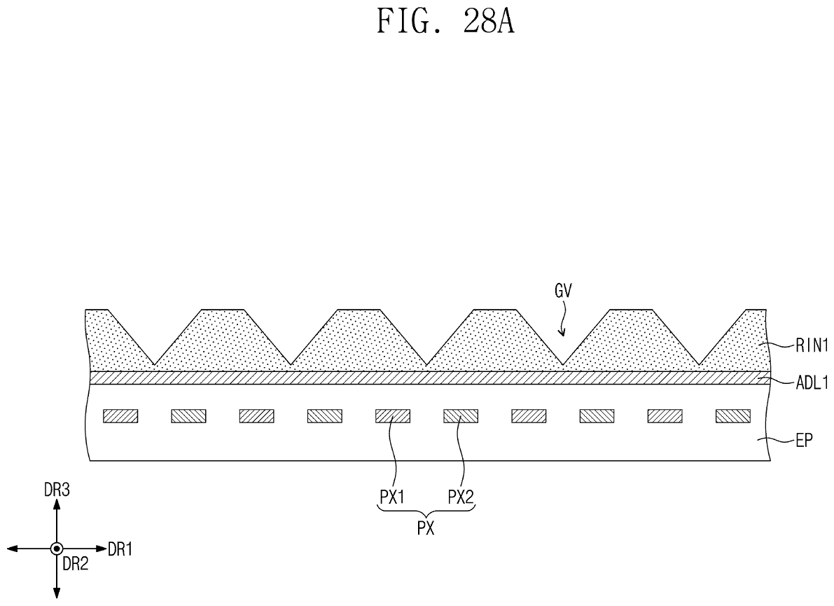

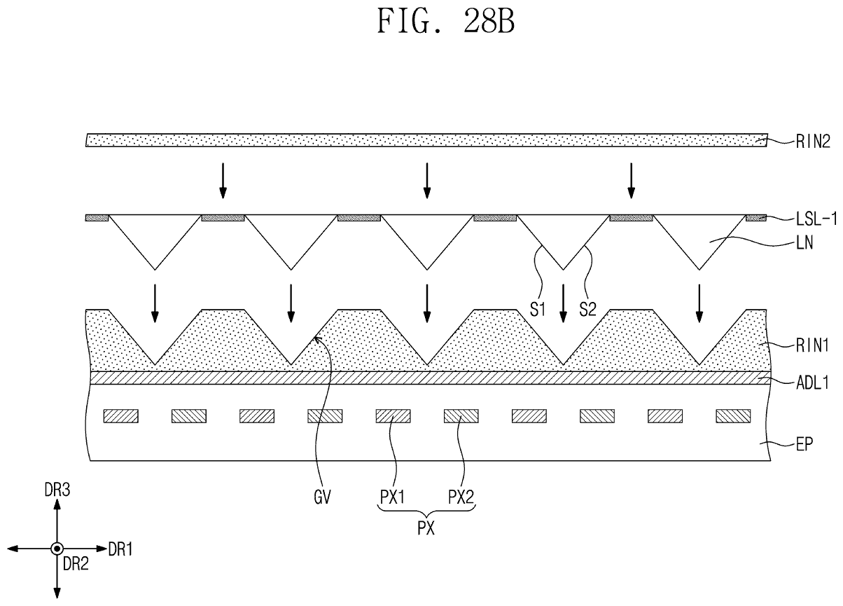

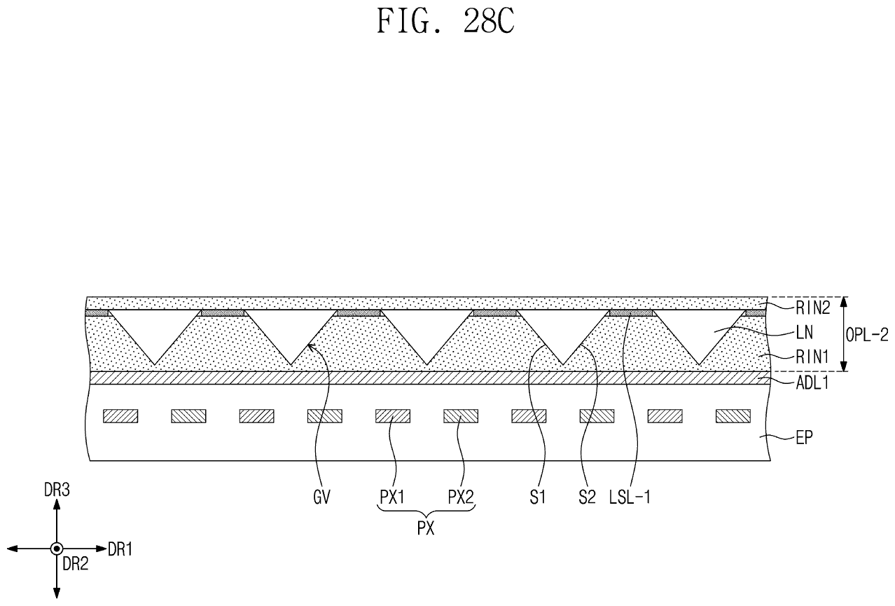

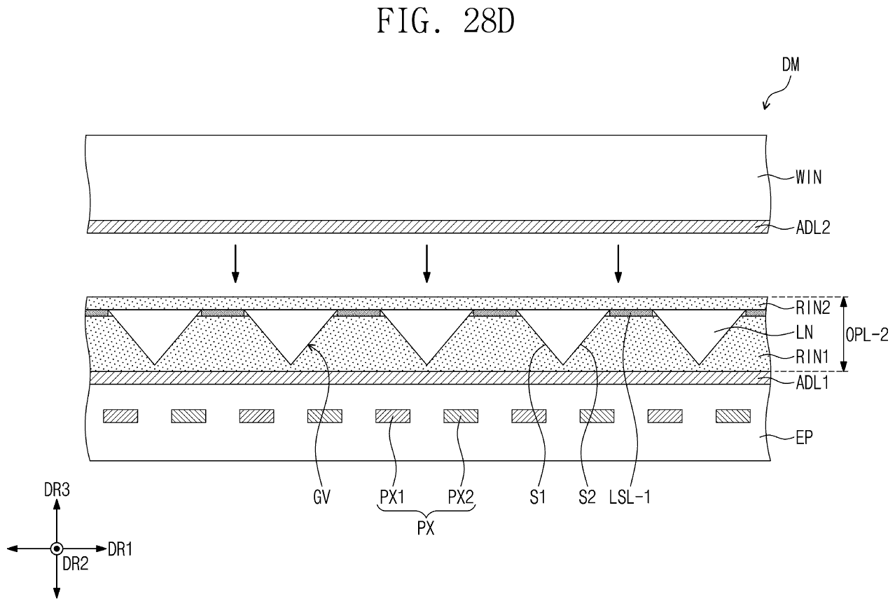

FIGS. 28A to 28D are schematic diagrams for describing a method of manufacturing the display module in FIG. 23.

By way of example, FIGS. 28A to 28D are cross-sectional views corresponding to FIG. 23.

Referring to FIG. 28A, an electronic panel EP may be prepared, and a first resin layer RIN1 having grooves GV defined therein may be provided on the electronic panel EP.

Referring to FIGS. 28B and 28C, lenses LN and light blocking layers LSL-1 may be provided on the first resin layer RIN1. The lenses LN may be provided in the grooves GV of the first resin layer RIN1, and the light blocking layers LSL-1 may be provided on upper surfaces of the first resin layer RIN1 between the grooves GV.

A second resin layer RIN2 may be provided on the lenses LN and the light blocking layers LSL-1, and an optical layer OPL-2 may thus be manufactured. Although not illustrated, the optical layer OPL-3 in FIG. 25 may also be manufactured in a similar manner to that for manufacturing the optical layer OPL-2.

Referring to FIG. 28D, a window WIN may be provided on the optical layer OPL-2 and the display module DM in FIG. 23 may thus be manufactured.

According to an embodiment of the inventive concept, lenses may be disposed on an electronic panel which may be wound and unwound, and a first image and a second image generated from the electronic panel may be provided leftward and rightward through the lenses. The lenses may be formed of transparent metal and serve to support an unwound electronic panel. Thus, when a rollable electronic panel is unwound, the electronic panel may be supported flat by the lenses, and the first image and the second image generated from the electronic panel may be dually provided to users respectively.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an electronic panel;
a plurality of lenses disposed on the electronic panel, arranged in a first direction, and extending in a second direction intersecting the first direction; and
a plurality of joint parts respectively disposed on the plurality of lenses and rotatably coupled to each other.

2. The display device of claim 1, wherein
a side of an h-th joint part and a side of an (h+1)-th joint part are adjacent to each other and coupled to each other to rotate with respect to a rotating axis parallel to the second direction so as to be defined as a rotary coupling portion,
the rotary coupling portion is disposed between an h-th lens and an (h+1)-th lens, and
h is a natural number.

3. The display device of claim 2, wherein a lower portion of the rotary coupling portion has a downwardly convex curved surface.

4. The display device of claim 3, further comprising:
a light blocking layer disposed under the lower portion of the rotary coupling portion.

5. The display device of claim 2, wherein the h-th lens and the (h+1)-th lens are respectively attached to a flat portion of the h-th joint part adjacent to the side of the h-th joint part and a flat portion of the (h+1)-th joint part adjacent to the side of the (h+1)-th joint part.

6. The display device of claim 1, further comprising:
a plurality of resin layers, between the plurality of lenses and the electronic panel, respectively disposed under the plurality of lenses.

7. The display device of claim 6, wherein the plurality of lenses have greater elastic modulus than the plurality of resin layers.

8. The display device of claim 6, wherein the plurality of lenses are respectively disposed in a plurality of grooves defined in the plurality of resin layers to face the plurality of lenses.

9. The display device of claim 6, further comprising:
a first adhesive layer disposed between the electronic panel and the plurality of resin layers.

10. The display device of claim 6, further comprising:
a window disposed on the plurality of joint parts; and
a second adhesive layer disposed between the window and the plurality of joint parts.

11. The display device of claim 10, wherein
a refractive index of the plurality of lenses is greater than a refractive index of the plurality of resin layers, and
a refractive index of the window is smaller than the refractive index of the plurality of lenses.

12. The display device of claim 1, wherein the plurality of lenses comprise a transparent metal.

13. The display device of claim 12, wherein the plurality of lenses comprise a metal material having a Knoop hardness in a range of about 1500 kg/mm² to about 2500 kg/mm².

14. The display device of claim 1, wherein when viewed in the second direction, the plurality of lenses each have a shape of an inverted triangle.

15. The display device of claim 1, wherein when viewed in the second direction, the plurality of lenses each have a downwardly convex shape.

16. The display device of claim 1, wherein
the electronic panel comprises a plurality of first pixels and a plurality of second pixels alternately disposed in the first direction, and
a pair of a first pixel and a second pixel which are adjacent to each other is disposed so that the first pixel and the second pixel are disposed on left and right sides of a corresponding lens, among the plurality of lenses, with respect to a central portion of the corresponding lens, when view on a plan.

17. The display device of claim 1, wherein
the electronic panel is wound or unwound according to rotation of the plurality of joint parts, and
in case that the electronic panel is unwound, the plurality of lenses support the electronic panel in a flat state.

18. A display device comprising:
an electronic panel;
a plurality of lenses disposed on the electronic panel, arranged in a first direction, and extending in a second direction intersecting the first direction;
a plurality of light blocking layers disposed between the plurality of lenses;
a first resin layer disposed between the plurality of lenses and the electronic panel and between the plurality of light blocking layers and the electronic panel; and
a second resin layer disposed on the plurality of lenses and the plurality of light blocking layers,
wherein the first resin layer and the second resin layer include a same material.

19. The display device of claim 18, wherein
the electronic panel comprises a plurality of first pixels and a plurality of second pixels alternately disposed in the first direction, and
a pair of a first pixel and a second pixel which are adjacent to each other is disposed so that the first pixel and the second pixel are disposed on left and right sides of a corresponding lens, among the plurality of lenses, with respect to a central portion of the corresponding lens, when view on a plan.

20. The display device of claim 18, wherein an upper surface of each of the plurality of lenses and an upper surface of each of the plurality of light blocking layers are disposed on a same plane.
